(19) United States
(12) Patent Application Publication
(10) Pub. No.: US 2004/0005018 A1
(43) Pub. Date: Jan. 8, 2004

(54) Receiver and method for WLAN burst type signals

(75) Inventors: Junjie Zhu, Singapore (SG); Noriyoshi Ito, Tokyo (JP)

Correspondence Address: VENABLE, BAETJER, HOWARD AND CIVILETTI, LLP, P.O. BOX 34385, WASHINGTON, DC, 20043-9998, US

(73) Assignee: Oki Techno Centre (Singapore) Pte Ltd, Singapore (SG)

(21) Appl. No.: 10/397,741

(22) Filed: Mar. 27, 2003

(30) Foreign Application Priority Data
Jul. 3, 2002 (SG) 200204072-3

(51) Int. Cl. H04L 27/06; H03D 1/00; H04L 27/28; H04K 1/10

(52) U.S. Cl. 375/340; 375/260

(57) ABSTRACT

The present invention relates to methods and devices for receiving signals in a Wireless Local Area Network (wireless LAN, or WLAN), particularly in the case that the signals are Orthogonal Frequency Division Multiplexed (OFDM) signals. A signal detection apparatus is disclosed for an OFDM receiver, having: means for determining the correlation of corresponding samples of two received preamble symbol samples, one said sample delayed a predetermined duration with respect to the other; signal detection being indicated when the correlation is greater than or equal to a threshold; wherein the threshold is dependent on the signal power of the received preamble symbols.

### FIELD OF THE INVENTION

The present invention relates to methods and devices for receiving signals in a Wireless Local Area Network (wireless LAN, or WLAN), particularly in the case that the signals are Orthogonal Frequency Division Multiplexed (OFDM) signals.

### DESCRIPTION OF THE PRIOR ART

Recently, OFDM-based wireless LAN standards IEEE 802.11a [1] and HIPERLAN/2 [2] [3] have been developed. The IEEE 802.11a standard is described in “Supplement to IEEE Standard for Information Technology—Telecommunications and Information Exchange between Systems—local and Metropolitan Area Networks—Specific Requirements—Part 11: Wireless LAN Medium Access Control (MAC) and Physical Layer (PHY) Specifications: High-Speed Physical Layer in the 5 GHZ band” IEEE Std 802.11a—1999. HYPERLAN/2 is described in Broadband Radio Access Networks (BRAN), “Broadband Radio Access Networks (BRAN); HYPERLAN type 2; Physical (PHY) Layer”. ETSI TS 101 475 V.1.1 (2000-04); and also in Broadband Radio Access Networks (BRAN), “Broadband Radio Access Networks (BRAN); HYPERLAN Type 2; Data link Control (DLC) Layer Part 1: Basic Data Transport Functions”, ETYSI TS 101 716-1 V.1.1 (2000-04).

For an OFDM-based wireless receiver, the following issues are significant: signal detection, AGC (automatic control gain), carrier recovery, symbol timing, frequency timing, and channel estimation. Important functions of a OFDM modem for WLAN include frequency and timing synchronization, since OFDM demodulation is very sensitive to frequency offset and ISI (Intersymbol Interference) caused by a multipath channel environment and which can result in serious timing errors, also if not corrected a phase shift is accumulated on each subcarrier, and this can bring about channel estimation errors.

FIG. 1 shows the structure of the OFDM PHY frame of IEEE 802.11a in which a preamble precedes all data symbols. This preamble is essential to perform packet detection, automatic gain control, symbol timing, frequency estimation and channel estimation.

The first part of the preamble consists of 10 repetitions of a training symbol with a duration of 800 ns, which is only a quarter of the FFT (Fast Fourier Transform) interval of a normal data symbol. These short symbols are generated by using only nonzero subcarrier values for subcarrier numbers which are a multiple of 4. There are two reasons for using relatively short symbols in this part of the preamble: Firstly, the short symbols provide a convenient way of performing Automatic Gain Control (AGC) and packet detection. Secondly, the short symbol period makes it possible to do symbol timing and a coarse frequency offset estimation with a large unambiguous range.

The short training symbols are followed by two long training symbols with a duration of that of a data symbol. There are two reasons for using long symbols in this part of the preamble: First, it makes it possible to do a precise frequency estimation on the long symbol. Second, the long symbols can be used to obtain reference amplitudes and phases for doing coherent demodulation.

At the end of the preamble, a special SIGNAL OFDM data symbol at the lowest 6 Mbit/s rate is sent which contains information about the length, modulation type and coding rate of the rest of the packet.

Finally, a variable number of data symbols are transmitted typically at a higher modulation level or rate. Each data symbol consists of a guard interval of 800 ns and a data IFFT interval of 3.2 us.

HIPERLAN/2 system has five different kinds of PHY bursts [2]:

1) Broadcast burst;

2) Downlink burst;

3) Uplink burst with short preamble;

4) Uplink burst with long preamble;

5) Direct link burst (optional).

Independently of the burst type each burst consists of two sections: a preamble and a payload. Each burst is started with a preamble section which is followed by a payload section. The content of preamble and payload section depends on the bust type.

There are five different types of burst format which are shown in FIG. 2: (a) a Broadcast burst, (b) a Downlink burst, (c) an Uplink burst with short preamble, (d) an Uplink burst with long preamble, (e) a Direct link burst.

The long training symbol is the same as for IEEE 802.11a, but the preceding sequence of short symbols may be different. A downlink transmission starts with 10 short symbols as in IEEE 802.11a, but the first 5 symbols are different in order to detect the start of the downlink frame. Uplink packets may use 5 or 10 identical short symbols, with the last short symbol being inverted. The difference between the preambles of IEEE 802.11a and HIPERLAN/2 is determined by their respective protocols.

However, at the PHY level, in principle the same receiver architecture may be used for IEEE802.11a bursts and some HIPERLAN bursts, in particular the non-downlink bursts. Signal detection, AGC and synchronization are not necessary for downlink burst. As the format of broadcast burst of HIPERLAN/2 is almost the same as that of IEEE802.11a, the same receiver architectures or methods can be used.

FIG. 3 shows the time and frequency structure of an OFDM packet having an IEEE 802.11 preamble. The packet starts with 10 short training symbols, using only twelve subcarriers, followed by two long training symbols and data symbols using the full fifty two subcarriers and containing four known pilot subcarriers used for estimating the reference phase. The ten short training symbols use a low order modulation for example QPSK (hence only the twelve subcarriers) in order to allow the receiver to synchronise itself with the incoming packet, before the actual data bits can be successfully decoded. The preamble, which is contained in the first sixteen microseconds of each packet comprises the ten short symbols on twelve subcarriers and the two long symbols on all fifty two subcarriers, is used to perform start of packet detection, automatic gain control, symbol timing, frequency estimation and channel estimation. All of these training tasks are necessary in order to successfully receive and decode the actual data bits.

As is known a cyclic prefix or guard interval (GI) is added to each data symbol to make the receiver more robust to multipath propagation. In particular, it is intended that the guard interval be large enough compared with the spread delay of the channel such that all significant received copies of the data symbol start within the guard intervals.

### SUMMARY OF THE INVENTION

The present invention aims to provide an improved or at least alternative methods and apparatus relating to receiving signals, especially OFDM signals in a WLAN.

There are provided various aspects relating to a receiver for an OFDM burst type signal, including: signal detection; automatic gain control; symbol timing; frequency offset tracking; and frequency tracking. Apparatus and methods relating to each of these aspects may advantageously be combined with apparatus and methods of the other aspects. Alternatively, each aspect may be used with prior art other aspects of the receiver.

In one aspect of the present invention, there is provided a signal detection apparatus for an OFDM receiver, having: means for determining the correlation of corresponding samples of two received preamble symbol samples, one said sample delayed a predetermined duration with respect to the other; signal detection being indicated when the correlation is greater than or equal to a threshold; wherein the threshold is dependent on the signal power of the received preamble symbols.

There is also provided a corresponding signal detection method comprising determining the correlation of corresponding samples of two received preamble symbols, one said sample delayed a predetermined duration with respect to the other; signal detection being indicated when the correlation is greater than or equal to a threshold; wherein the threshold is dependent on the signal power of the received preamble symbols.

This uses the signal power of samples of the received preamble symbols over the number of short symbols required for signal detection to set the threshold for the correlation method of detecting a signal. This has the advantage of improving accuracy of detection especially by increased tolerance of noise. This is because the threshold is dynamic and dependent on signal reception conditions.

Preferably the apparatus further comprises means for determining the signal power of the symbol samples, and means for determining said threshold from said signal power and the signal power determining means may further comprise means for accumulating the difference between said sample signal powers, with the predetermined duration preferably being of one preamble symbol.

The correlation determining means preferably comprises means for determining the product of a said sample and the conjugate of a said delayed sample, means for accumulating said product over an integration window; and means for accumulating the difference between said product at the beginning and end of said window.

The samples are preferably a first and a last sample in a correlation window having a length of one preamble symbol.

In a second aspect of the present invention, there is provided an Automatic Gain Control apparatus for an OFDM receiver, having: means for determining the average power of received preamble symbols in order to set an appropriate AGC level; means for determining a first AGC level based on the average power of a first number of symbols and; means for determining a second AGC level based on the average power of a second number of subsequent symbols.

There is also provided a corresponding automatic gain control method comprising: determining the average power of received preamble symbols in order to set an appropriate AGC level; determining a first AGC level based on the average power of a first number of symbols and; determining a second AGC level based on the average power of a second number of subsequent symbols.

This allows symbol timing and frequency offset estimation to start earlier and use more short symbols thus increasing their accuracy by allowing them to rely on a coarse AGC. It also uses more short symbols overall for (fine) AGC and thus increases its accuracy for data recovery. Coarse AGC is sufficient for starting symbol timing and frequency offset estimation when the modulation rate is low i.e. QPSK, the fine AGC being implemented before high level modulation such as 64 QAM where accurate AGC is more critical. Note that this also allows both coarse and fine frequency estimation to be done within the first preamble.

By comparison, prior art AGC measures the signal power of the first seven short symbols in the first preamble, this accumulated total being averaged to determine the appropriate gain level. However because this AGC uses the first seven short preamble symbols, symbol timing and frequency offset estimation cannot be started until the 8^{th} short symbol, thus leaving only three symbols and hence limiting accuracy. This also results in the fine frequency estimation having to utilise the second preamble.

By using a two-stage AGC method in which a coarse AGC is determined one short symbol after signal detection which is normally only two short symbols, symbol timing and frequency offset estimation can start much earlier and thus their accuracy is improved. A second stage of AGC runs in parallel with these functions and resets the AGC at the end of the short preamble burst for high accuracy data recovery using the second stage AGC.

Preferably said first AGC level determination is triggered by signal detection and said second AGC level determination may be triggered by symbol timing acquisition.

Preferably, the determining means comprises an infinite impulse response filter and the AGC level determination means may utilise a look-up table to correlate said average power with an AGC level.

Preferably, the second number of symbols is larger than said first number.

Preferably an IIR filter is designed to average the measured power for 2^{nd} AGC in order to reduce the required buffer.

In a third aspect of the present invention, there is provided a frequency tracking apparatus for an OFDM receiver having: means for determining the correlation of corresponding samples of two received pilot carrier symbols, one said sample delayed a predetermined duration with respect to the other; means for integrating said correlation over an integration window and; means for determining a frequency tracking error from the sum of said integration.

There is also provided a corresponding symbol timing method comprising: determining the correlation of corresponding samples of two received pilot carrier symbols, one said sample delayed a predetermined duration with respect to the other; integrating said correlation over an integration window and; determining a frequency tracking error from the sum of said integration.

By using an integration window T_{w} which is longer than one short symbol, for example nine short symbols, this results, graphically, in an improved measure of P(d) for estimating the symbol timing start time. In order to produce a clear peak as opposed to a plateau in P(d), sum of the duration or length of the integration window and that of the delay between corresponding samples in different symbols should be greater or equal to the number of symbols measured—10 in IEEE802. This in turn provides for easier and more accurate estimation of the symbol timing.

By comparison, prior art symbol timing arrangements use the metric P(d) having an integration window T_{w} equal to one short preamble symbol (T_{d}). However such a metric does not indicate precisely the symbol timing, instead producing, graphically, a plateau which makes precise detection difficult.

Preferably the apparatus further comprises correlation determining means and integration means for symbols from a number of other pilot carriers; said frequency tracking error being determined from the average integration sum of said pilot carriers.

In a fourth aspect of the present invention, there is provided a frequency offset estimation apparatus for an OFDM receiver, having: means for determining a first frequency offset having means for determining the correlation of corresponding samples of two received preamble symbol samples a first predetermined delay duration apart; means for determining a second frequency offset having means for determining the correlation of corresponding samples of two received preamble symbol samples a second predetermined delay duration apart, said second delay duration being different from said first delay duration; and means for combining said first and second frequency offsets in order to determine said frequency offset estimation.

There is also provided a corresponding frequency offset method comprising: determining a first frequency offset by determining the correlation of corresponding samples of two received preamble symbol samples a first predetermined delay duration apart; determining a second frequency offset by determining the correlation of corresponding samples of two received preamble symbol samples a second predetermined delay duration apart, said second delay duration being different from said first delay duration; and combining said first and second frequency offsets in order to determine said frequency offset estimation.

By using two parallel branches for frequency estimation, high precision combined with unambiguous frequency offset estimate provides a better coarse frequency estimation than the prior art method, for example using eight short symbols instead of the prior art three short symbols and the second preamble.

By comparison, prior art frequency offset estimation methods utilise a first coarse measure using the last three short symbols of the first preamble, and a second fine measure using the second preamble including two and a half long training symbols. With respect to the coarse measurement, to achieve maximum precision a large number of symbols should be used; however, in order to avoid the 2π ambiguity of the phase, a larger estimation range must be used and this requires a small number of symbols. Hence the compromise of three short symbols, necessarily resulting in a less accurate estimation of frequency offset.

Preferably the apparatus further comprises means for integrating each said offset determination over respectively first and second predetermined integration windows. The sum of the delay and integration window durations for the first and second frequency offset determining means may be equal and the receiver may preferably receive 10 preamble symbols, the first delay time being 1 preamble symbol duration and the second delay time being 4 preamble symbol durations. The first integration window length may be 7 preamble symbol durations and said second integration window length may be 4 preamble symbol durations.

The combining means preferably comprises signal processing means arranged to calculate the estimate according to the equation:

$$Δ \hat{f} = \frac{{\hat{φ}}_{m} + 2 π \cdot z}{2 π m {L}_{short} T}$$

In a fifth aspect of the present invention, there is provided a symbol timing apparatus for an OFDM receiver having: means for determining the correlation of corresponding samples of two received preamble symbols, one said sample delayed a predetermined duration with respect to the other; means for determining the maximum correlation value within a predetermined integration window, said maximum value indicating the start of a symbol; wherein the integration window duration is not equal to said delay duration.

A method of symbol timing in an OFDM receiver is also provided, the method comprising: determining the correlation of more than two identical short preamble symbols; determining the symbol timing based on the maximum correlation value within a predetermined integration window; and wherein the integration window duration is not equal to the delay duration.

Preferably the integration window duration is greater than said delay duration and said correlation determining means may comprise: means for determining the product of a sample of a said received preamble symbol and the conjugate of a corresponding sample of said delayed symbol; means for accumulating said product over said integration window; and means for accumulating the difference between said product at the beginning and end of said integration window.

Preferably the apparatus receives a predetermined number of preamble symbols and wherein the sum of the delay duration and said integration window duration are greater than or equal to the duration of said preamble symbols and the number of symbols may be 10, the delay duration may be 1 symbol duration, and the integration window may be nine symbol durations. In other preferred alternatives, the number of symbols may be 10, the delay duration may be 1 symbol duration, and the integration window may be 7 symbol durations or the number of symbols may be 10, the delay duration may be 4 symbol durations, and the integration window may be 6 symbol durations.

The receiver may be arranged to support various wireless LAN systems including those using the conventional IEEE 802.11a and HIPERLAN/2 protocols.

### BRIEF DESCRIPTION OF THE FIGURES

Non-limiting embodiments of the invention will now be described, for the sake of example only, with reference to the following figures in which:

FIG. 1 shows the format of a OFDM PHY frame of the known IEEE 802.11a standard;

FIGS. 2(a)-(e) shows PHY burst structures of five types of burst in the known HIPERLAN/2 standard;

FIG. 3 shows the time domain structure of an OFDM packet having 52 sub-carriers;

FIG. 4 is a block diagram of a WLAN OFDM receiver;

FIG. 5 shows preamble symbols in the time domain;

FIG. 6 is an implementation block diagram of the algorithm for deriving P(d) in the signal detection algorithm of the embodiment;

FIG. 7 is an implementation block diagram of the algorithm for measuring signal energy in the embodiment;

FIGS. 8(a) and (b) illustrates the 2-stage AGC process used in the embodiment;

FIGS. 9(a)-(c) illustrates the timing metric of the AWGN channel of the embodiment;

FIG. 10 illustrates three possible DFT windows;

FIG. 11 illustrates an operation model of symbol timing detection used in the embodiment;

FIG. 12 shows a symbol timing detection algorithm used in the embodiment;

FIG. 13 illustrates the effect of frequency offsets;

FIG. 14 is a block diagram of a carrier and timing synchronisation algorithm used in the embodiment;

FIG. 15 is a block diagram of a phase shift compensation algorithm used in the embodiment;

FIG. 16 is a diagram illustrating the pilot carriers in an OFDM symbol;

FIG. 17 is a block diagram of a frequency tracking algorithm;

FIG. 18 shows simulation results B of the rms frequency tracking error obtained by the embodiment; and

FIG. 19 shows simulation results of the BER performance of the embodiment in an exponential decaying multipath Rayleigh channel.

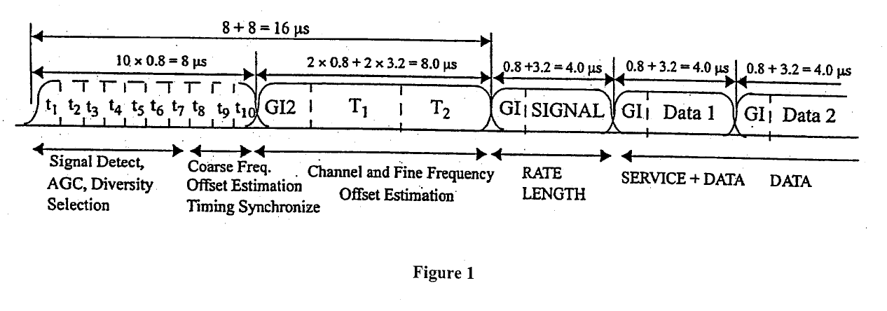

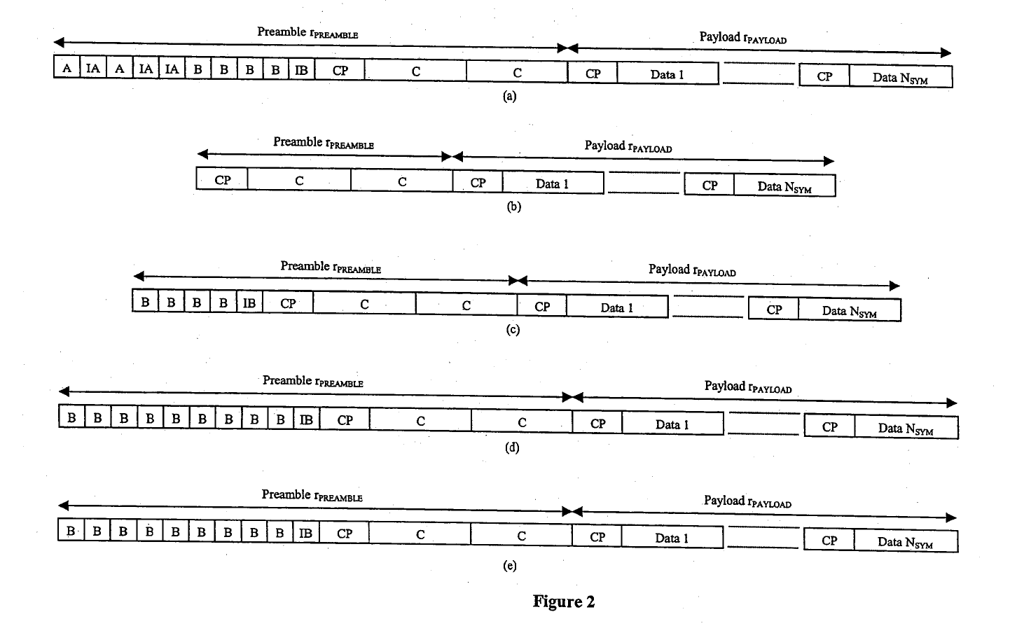

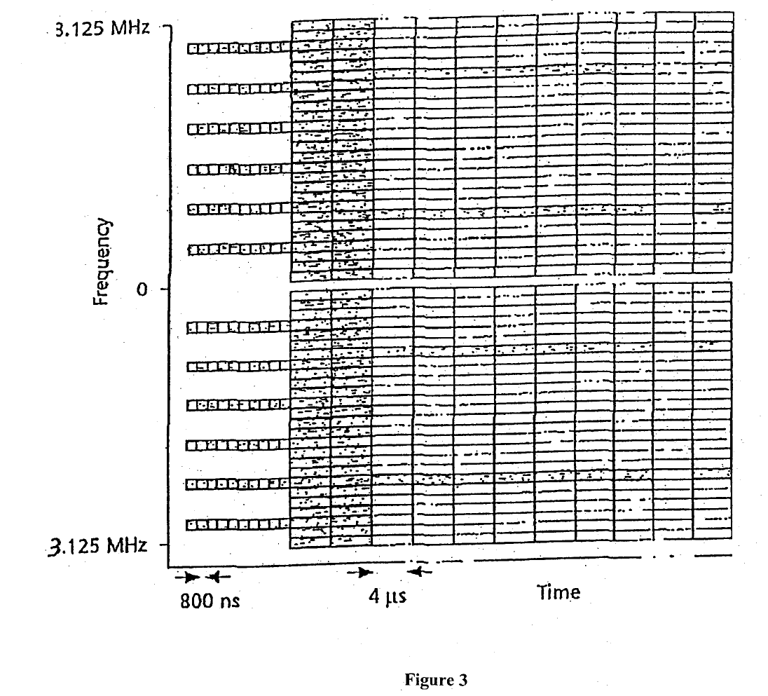

### DETAILED DESCRIPTION OF THE PREFERRED EMBODIMENTS

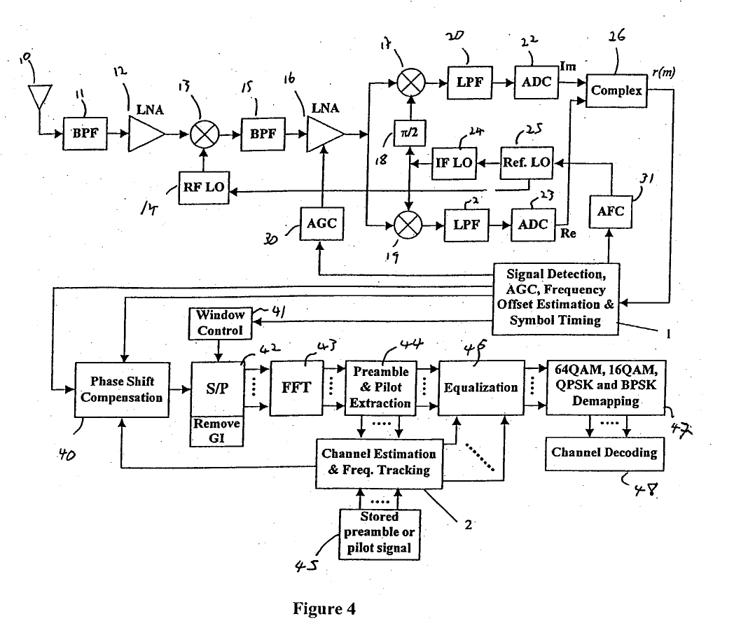

FIG. 4 shows a typical architecture for an OFDM packet based receiver. Such a receiver may be used in a mobile terminal for example. The RF section comprises an antenna 10, a band-pass filter 11, and a low-noise amplifier 12. The IF section comprises a mixer 13 which multiplies the incoming RF signal from low-noise amplifier 12 with a local RF oscillator 14 signal, the product of which is fed to a band-pass filter 15, then to a variable low-noise amplifier 16, the output of which is split into in-phase (real) and quadrature (imaginary) circuit branches. These branches each comprise a further mixer 17 or 19 which receives the intermediate frequency signal from the variable low-noise amplifier 16 and which also receives a signal from an intermediate frequency local oscillator 24, the input to mixer 17 being delayed by 90° or a quarter phase using phase delaying component 18. The outputs of mixers 17 and 19 are each fed to a low-pass filter 20 and 21 respectively, then on to an analog-to-digital converter 22 and 23 respectively, the outputs of which are fed to a complex combiner 26, in this example an I/Q LPF. The resulting signal r(m) is the base band OFDM signal, which contains both the preamble and data symbols of the incoming packet.

A synchronisation function 1 receives the base band OFDM signal and uses the preamble of the incoming packet to perform a number of sychronisation functions. These include signal detection, automatic gain control, frequency offset estimation, and symbol timing. The synchronisation function 1 controls gain controller 30, frequency controller 31, a phase shift compensation function 40, and a window control function 41.

The gain controller 30 in turn controls the variable low noise amplifier 16 and is intended to compensate for the bursty nature and varying signal level of the incoming signals, with the aim of providing a reasonably uniform signal level output from low-noise amplifier 16. This improves the accuracy of the receiver, and in particular the accuracy of the analog to digital converters 22 and 23 which will be optimised for a particular range of signal level.

The frequency controller 31 controls a reference local oscillator 25 for the receiver, and this in turn controls all other local oscillators in the receiver, including the radio frequency local oscillator 14 and the intermediate frequency local oscillator 24.

The base band signal r(m) is passed on to a phase shift compensation function 40 which is also controlled by the synchronisation function 1 and a frequency tracking function 2. The phase shift compensation function 40 is described in detail below.

The output of the phase shift compensation function 40 is passed on to a Serial to Parallel digital signal converter 42 which additionally removes the guard interval signal components from each symbol. The Serial to Parallel function 42 converts a predetermined number of incoming digital bits (samples) corresponding to the combined samples of the base band signals from the ADC's 22 and 23 into a word corresponding to an OFDM symbol. When the FFT function is processed, a predetermined number of incoming samples are needed for input to the FFT block simultaneously. The predetermined number of samples, which are partially processed by the FFT and partially removed of the guard interval, represent a received OFDM symbol. It is important that the word corresponding to the OFDM symbol starts at the right sample bit in the incoming bit stream in order for accurate symbol recovery. It is therefore important to accurately determine the symbol timing, or start of symbol.

The length of each symbol is known in advance and so an appropriate window length is applied to the incoming base band signal to retrieve individual symbols. In doing this the guard interval signal components are removed. The timing of the window used to retrieve each separate symbol is controlled by the control window function 41, which in turn is controlled by the synchronisation function 1 once the symbol timing has been determined. The window is arranged to overlap the guard interval slightly in order to ensure that the start of each copy of a symbol arriving from multiple paths is within the window.

The individual OFDM symbols are fed from the Serial to Parallel function 42 to a fast fourier transform function 43 which separates the symbol values on each subcarrier (12 or 52). These values are passed on to a preamble and pilot extraction function 44 which removes the preamble values and the values associated with the four pilot subcarriers. These values are used for the channel estimation and frequency tracking function 2.

The channel estimation and frequency tracking function compares the incoming preamble and pilot values with stored preamble and pilot values 45 to determine the effect of the air interface channel, and to instruct the equalizer 46 to correct for this channel. This function 2 also monitors the subcarrier frequencies over time and controls the phase shift compensation function 40 to compensate for any drift over this time.

The channel equalization function 46 corrects for the effects of the air interface channel between the transmitter and the receiver antennas. After channel estimation and equalization, the signal for each subcarrier is demapped into binary data according to the modulation type of the subcarrier. The data sequences are then decoded. These functions are carried out by demapper or demodulator 47 and channel decoder 48 respectively.

Embodiments of the invention provide improved methods of: signal detection; automatic gain control; frequency offset estimation; symbol timing; and frequency tracking as described below.

A receiver according to an embodiment of the invention employs novel functions 1 and 2 which are described in detail below. These perform the packet signal detection, AGC (automatic gain control) offset frequency estimation, symbol timing and frequency tracking functions.

The embodiment provides that these functions utilise overlapping preamble symbols in order to maximise their accuracy. At the baseband, the receiver firstly detects the start of the signal and measures the incoming signal power for the AGC process. Whilst performing the AGC function, the frequency offset estimation and symbol timing functions are also performed. This is achieved by using at least some of the same symbols for each function. In other words these functions use overlapping training symbols in the preamble.

Conventionally the above operations are done one at a time using separate preamble symbols. For example the first seven short training symbols are used for signal detection and AGC. The remaining three short training symbols are then used for coarse frequency offset estimation and symbol timing. Then the two long training symbols in the preamble are used for fine frequency offset estimation and channel estimation.

We now describe in detail the operations performed by the units 1 and 2.

1. Signal Detection

Since the radio environment in which the wireless LANs operate is usually adverse, the transmitted signal is distorted by multipath fading, collapsed with thermal noise, or interfered by other signals. This distorted signal may cause the receiver to make incorrect decisions, declaring an acquisition while missing the correct position, or just missing the detection. In both cases the packet will be declared lost by the receiver after a time-out period and the transmitter has to retransmit the packet while other users have to wait. Such packet loss will not only decrease the overall system throughput but will also increase the mean transmission time of packet and, hence, a longer delay can be expected.

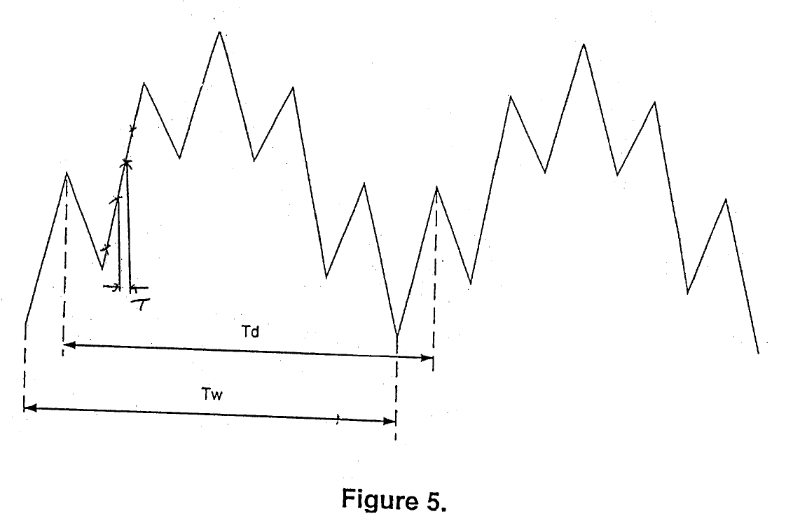

Prior art units 1 detect a signal by measuring the correlation of incoming signals. Consider two repeated training symbols as shown in FIG. 5 that are identical to each other at the receiver except for a phase shift caused by the carrier frequency offset. If the conjugate of a sample from the first symbol is multiplied by the corresponding sample from the second (delay time T_{d}=Tₛₕₒᵣₜ later), the effect of the channel should be cancelled and the products of each of these pairs of samples will have approximately the same phase. So the magnitude of the sum will be a large value. When this correlation value is larger than a detection threshold, the receiver is informed that a burst is arriving. The detection threshold is normally set by experiment.

The present embodiment provides that the energy of received signal samples is measured. The power of each received signal sample is calculated and integrated for a duration of Tw. If the sample interval is T, Tw=WT, i.e. W samples are processed to calculate the energy which can be written as

$$R ( d ) = {\sum }_{m = 0}^{w - 1} \vert r ( d + m ) {\vert}^{2}$$

where W is window length, which represents the number of samples used to compute the signal energy within the window, d is a time index corresponding to the first sample in a window of W samples, and m is the sample index of the window.

The R(d) can be obtained by the following iterative computation.

R(d+1)=R(d)+|r(d+w)|²|−|r(d)|²

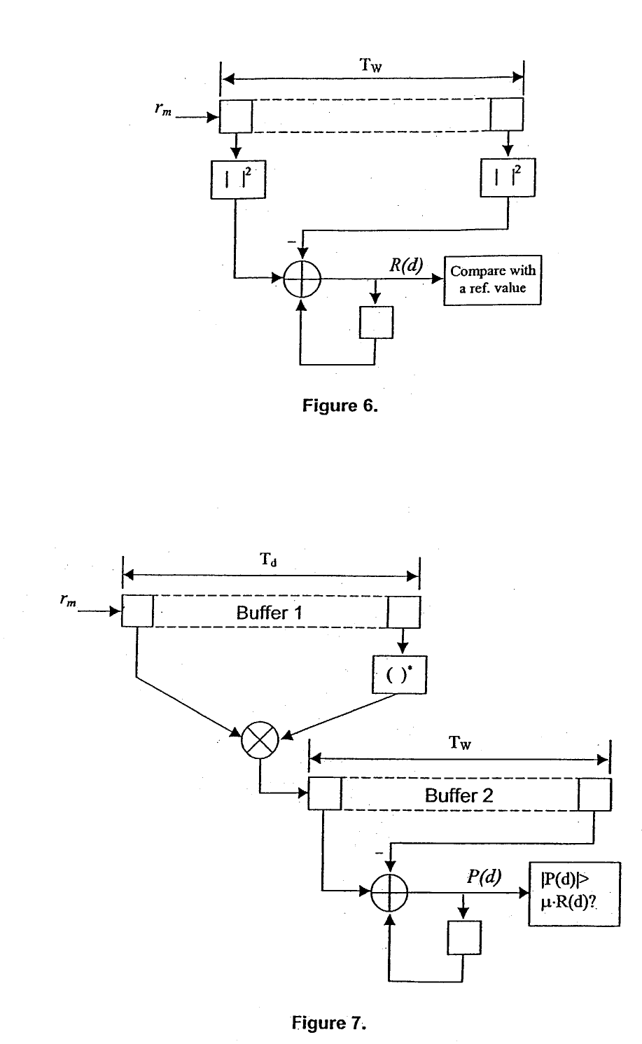

The implementation diagram of measurement of received signal energy is shown in FIG. 6.

The received signal samples are input to a buffer with size of W samples. The buffer is initially set to be zero. The powers of the first and the last sample in the buffer are calculated. The power difference is accumulated as time goes by. The output of this circuit is the measured energy of the received signal samples over a window length of one short symbol. It can be seen that as the leading edge of the window hits the start of a symbol as shown in FIG. 5, the energy measured begins to accumulate. The output R(d) is compared with a reference threshold which should satisfy the minimum receiving signal power specified in the IEEE or Hiperlan standard and is adjusted by experiment. In other words, the threshold is set so that as long as the received signals satisfy the minimum requirement of the received signal power, R(d) will exceed the threshold.

Once R(d) exceeds the threshold, it signals that there is possibly an incoming signal. But high noise and interference can also lead to R(d) exceeding the threshold. So R(d) is provided for the signal detection reference threshold in FIG. 7; ie |P(d)|>μR(d).

Referring to FIG. 7, r(m) denotes the sampled received signal, the sum of the products of the signal sample pairs is:

$$P ( d ) = {\sum }_{m = 0}^{W - 1} ( {r}^{*} ( d + m ) r ( d + m + D ) ) \qquad ( 1 )$$

where d is a time index corresponding to the first sampled training symbol in a window of samples and D is the number of delay samples between symbols in the preamble. W is the number of samples for the length of the correlation window. This window slides along in time as the receiver searches for the first training symbol. T is a sample interval, so the delay time T_{d}=DT and the length of the integration window T_{w}=WT. Preferably T_{w}=T_{d}=Tₛₕₒᵣₜ. This has the advantage of less hardware complexity due to smaller buffer size compared with the case of T_{w}>Tₛₕₒᵣₜ. Secondly, this part of the hardware can be reused by the function of frequency offset estimation and symbol timing. Thirdly, there is fast acquisition due to small delay and integration duration.

For signal detection, the delay time T_{d} is set to be one short symbol i.e. T_{d}=Tₛₕₒᵣₜ=16T_{c} where T_{c} is chip interval of 50 ns. If the sampling rate is equal to the chip rate, T_{c}=T. Normally, oversampling is needed, and the integration window length T_{w} is set to be Tₛₕₒᵣₜ.

P(d) can be obtained by the iterative formula:

P(d+1)=P(d)+r*(d+W)r(d+W+D)−r*(d)r(d+D)

A corresponding implementation diagram is shown in FIG. 7. The received signal samples rₘ are input to the Buffer1 which has a size of D samples. The first sample of Buffer1 is multiplied with the conjugate of the last sample of Buffer1. The product is input to Buffer2 which has a size of W samples. The difference of the first and the last sample in the buffer2 is accumulated over time. The Buffer1 and Buffer2 are initially set to be empty. The output of this circuit is the auto-correlation of the received samples. It means that the auto-correlation of a sequence of received samples with delay time of Td=DT and integration duration of Tw=WT is calculated.

Because P(d) is also used for symbol timing and frequency synchronization which will be discussed later, the buffer 2 in FIG. 7 can be shared by both signal detection and synchronization functions. Then the absolute value of P(d), |P(d)| is used to compare with a detection threshold dependent on R(d) to determine whether the desired signal is detected.

The detection threshold is important for the performance of signal acquisition. The embodiment proposes using the measured energy R(d) of the received signal to generate the detection threshold which is adjusted by experiment. If |P(d)| doesn't exceed the threshold, the detection function will continue to calculate |P(d)| until it exceeds the threshold. Most packets or signal bursts will be detected within two short symbols. If |P(d)| doesn't exceed the threshold over the first preamble, the packet will be lost. Through computer simulation, it has been shown that the probability of detecting a packet within two short symbols is higher using the method of the embodiment than using the prior art methods.

This detection method can be applied for both IEEE 802.11a and Hiperlan protocols as these both contain an initial preamble of respective training symbols. In IEEE 802.11a, the 1^{st} preamble of the received burst consists of 10 repeated training symbols. In Hiperlan, the first preamble structure depends on the burst type, but each contains at least five repeated training symbols.

2. AGC (Automatic Gain Control)

Once the transmitted signal is detected, the receiver is triggered to start AGC. AGC adjusts the gain of a variable gain amplifier (VGA) 16 to accommodate widely varying signal power levels and to maintain a signal with constant power level into the base-band A/D converters 22, 23. Then full use can be made of the A/D resolution and the signal to noise ratio in the digital signal processor is maximized.

Conventionally the first 7 short symbols are used for signal detection and AGC. The control gain is applied to both the symbols for synchronization and the symbols carrying data. The preambles modulated by QPSK require less accurate control gain than the data symbols, especially those modulated by 64 QAM. To meet the requirement of all kinds of symbols, conventional AGC needs a long period to achieve an accurate control gain.

In the embodiment, AGC operation is divided into two stages. At the first stage, coarse AGC is done when the signal is detected. The coarse control gain is used to adjust the subsequent short symbols until the symbol timing and coarse frequency offset estimate is obtained. At the second stage, fine AGC is done following symbol timing. The fine control gain is used to adjust the subsequent second preamble and data symbols.

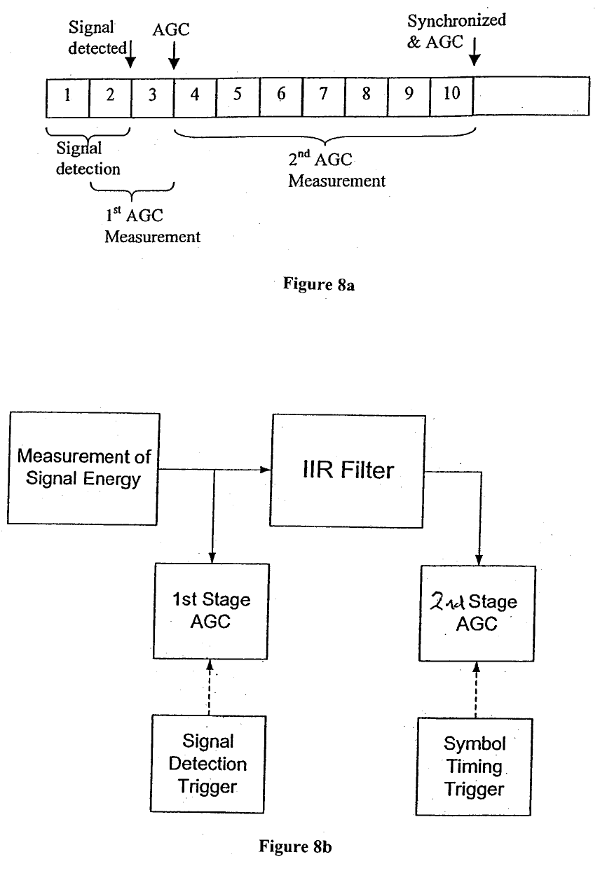

The two-stage AGC method of the embodiment is illustrated in FIGS. 8a and 8b. At the first stage, the received signal energy is measured firstly as described above with respect to FIG. 6. AGC reuses the energy measurement circuit which has T_{w}=Tₛₕₒᵣₜ. At the moment when a signal is detected, the first stage AGC is triggered. Preferably two short symbols are measured. At the time of signal acquisition which is mostly finished within two short symbols, the receiver assumes that at least one short symbol is received and measures one more short symbol then averages the two symbols energy. The mean short symbol signal energy R(d) is used to calculate the AGC gain. AGC gain is obtained by searching a lookup table according to the output of the measurement circuit of received signal energy. The lookup table is constructed according to the following formula.

$$G = {G}_{i} \sqrt{\frac{{R}_{ref}}{R ( d )}}$$

Where G is the AGC gain, Gᵢ is the initial AGC gain and R_{ref} is the reference energy which is proportional to the mean value of the transmitted one short symbol energy. Because AGC function interacts at the IF and RF parts of the receiver, the theoretical reference energy R_{ref} cannot be calculated only on baseband. Normally it's adjusted by experiment and hardware debugging. The obtained control gain is used to adjust the VGA 16 immediately. At the second stage, the output of the energy measurement circuit is delivered to an IIR (Infinite Impulse Response) Filter which is triggered by signal detection. The input and output of the IIR filter are updated every Tₛₕₒᵣₜ=800 ns. As is known an IIR filter provides a weighted average of its inputs and so its output at the end of the short preamble will be the average short symbol energy over perhaps 7 short symbols. When correct symbol timing is detected, the second AGC adjustment is triggered. The output of the IIR filter will be used to search the control gain in the same way as at the first stage.

In the first step of AGC, one or preferably two short symbols of the first preamble is measured to obtain an AGC gain and then the amplifier 16 before the ADC (22,23) is adjusted. During the second step of AGC, the following short symbols are measured to update the AGC gain to a more accurate value. If signal detection occurs after two short symbols, coarse AGC after a further one short symbol, then fine AGC will utilise 7 short symbols as shown in FIG. 8a. This provides a more accurate measure than prior art methods, whilst at the same time allowing symbol timing and frequency offset estimation to start much earlier. The number of measured short symbols in the second stage is variable and determined by symbol timing. The variable gain amplifier 16 is then adjusted again to provide a constant gain for the following incoming signals including the two long preamble and data symbols for one frame.

In this embodiment, a 2-step AGC process strategy is adopted as shown in FIG. 8. In the first step of AGC, typically two short symbols of the first preamble are measured to obtain an AGC gain and then the amplifier 16 before the ADC (22,23) is adjusted. Two short symbols are typically used as this is how many symbols are typically required for signal detection, which triggers the first stage of AGC. During the second step of AGC, typically the following seven short symbols are measured to update the AGC gain to a more accurate value. The variable gain amplifier 16 is then adjusted again to provide a constant gain for the following incoming signals for one frame. Note the second AGC adjustment is triggered by the symbol timing function (described below). When correct symbol timing is determined usually after the remaining seven short symbols, AGC gain for the second AGC adjustment is completed and the variable gain amplifier adjusted accordingly.

3. Symbol Timing Synchronization

The objective of symbol timing is to know when the symbol starts. A timing error gives rise to a phase rotation of the subcarriers. This phase rotation is largest on the edges of the frequency band. There is usually some tolerance for symbol timing errors when a cyclic prefix is used to extend the symbol as is known. That is, if a timing error is small enough to keep the channel impulse response within the cyclic prefix, the orthogonality between subcarriers is maintained. In this case a symbol timing delay can be viewed as a phase shift introduced by the channel, and the phase rotations can be estimated by a channel estimator. If a time shift is larger than the cyclic prefix, ISI (Inter Symbol Interference) will occur. In OFDM systems, a guard interval (GI), which is copied from the last part of a symbol, is inserted before the symbol. Therefore, in order to reduce ISI and phase rotation, the estimation timing of the start of the symbol should be within the guard interval and preferably as near to the start of the symbol as possible.

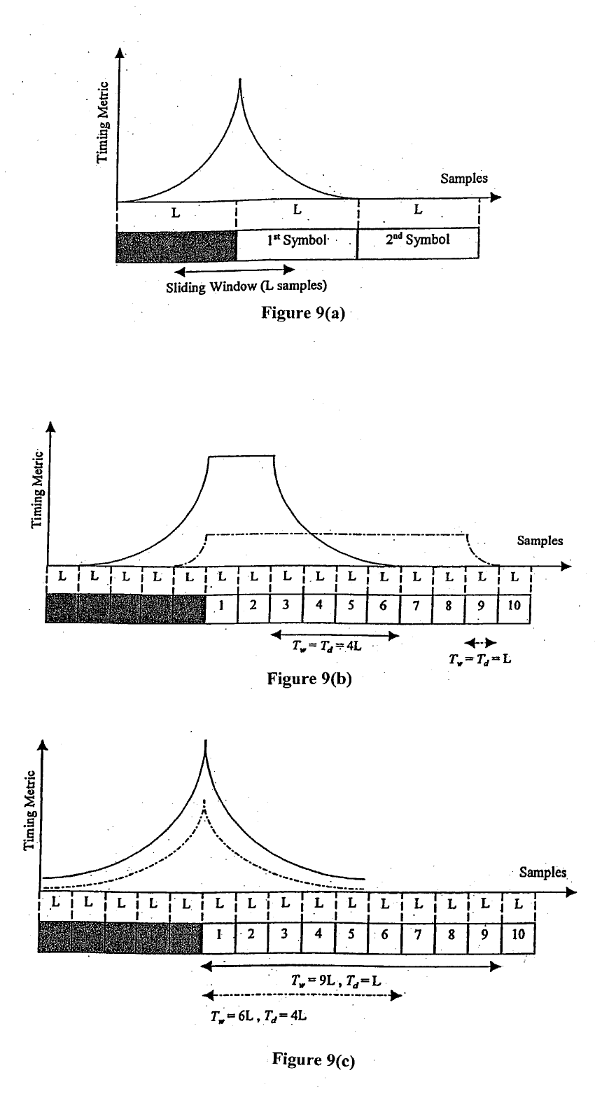

The auto correlation or detection metric P(d) is also used as the timing metric. FIG. 9(a) shows an example of the timing metric value as a window slides past two repeated training symbols for the AWGN channel for an OFDM signal. The peak value of the timing metric determines the start time of the received symbol. Note however that for more than two repeated training symbols (as in the case of practical systems), the timing metric P(d) will produce a plateau as shown in FIG. 9(b). Such a plateau makes precise detection difficult.

For a multipath channel, the timing metric reaches a plateau which has a length equal to the length of the channel impulse response so that there is no ISI within this plateau to distort the signal. This plateau is caused by delay spread and adds to the above timing metric plateau. Although it is possible to detect the start of the frame by measuring the edge of the plateau, this plateau leads to some uncertainty as to the symbol timing and results in increased hardware complexity.

In this OFDM synchronization technique there are several parameters of importance. One parameter is the window length, T_{w}=WT, which represents the number of samples pairs used in the metric. The other is the delay between two repeated symbols, T_{d}=DT. Here the equation of the timing metric is the same as that of the detection metrics:

$$P ( d ) = {\sum }_{m = 0}^{W - 1} ( {r}^{*} ( d + m ) r ( d + m + D ) )$$

In conventional methods, T_{w} is considered to be equal to T_{d}. In FIG. 9(b), the metric curve with W=D=L and 4L is shown where L is the number of samples in one symbol.

It is observed that if T_{w} is increased, i.e. the number of samples processed is increased, the peak value and SNR of the metric will increase as shown by the higher plateau. Therefore, T_{w} doesn't have to be equal to T_{d}. Referring to FIG. 9(c), it can be seen that for a preamble with ten short training symbols and W=9L, T_{d}=L, the timing metric is a more readily detectable peak. The start time of the frame is detected when this peak value of the metric is detected. To achieve a peak, the sum of T_{w} and T_{d} should be the number of processed samples L which corresponds to the repeated symbols. For example, in FIG. 9b, T_{w}=T_{d}, but T_{w}+T_{d}<10L which is the number of processed samples, therefore a plateau is formed after the receiver received T_{w}+T_{d} samples and until all the repeated symbols are received. In other words, a peak will result from the sum of T_{w} and T_{d} being equal to or greater than the number of samples processed. In FIG. 9c, T_{w}≠T_{d} and T_{w}+T_{d}=10L, a peak is achieved only when all repeated symbols are received; in this example at the end of the 10 short preamble symbols. By using this method it is possible to have a low sample rate eg L=1 which reduces hardware complexity and cost.

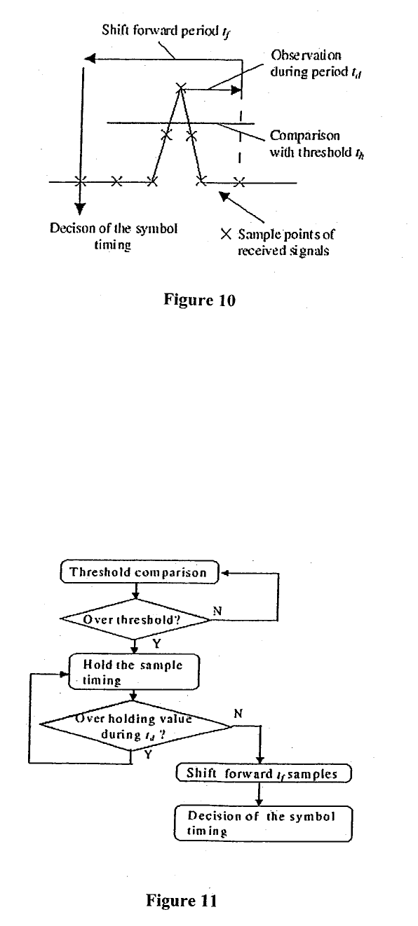

The peak detection algorithm and the operation model of the symbol timing detection are shown in FIG. 10 and FIG. 11, respectively. The algorithm is as shown in FIG. 7, but using the timing metric discussed above i.e. T_{w}=9T_{d}. The peak values of the timing metric |P(d)| are located sequentially so as to limit memory requirements. When |P(d)| exceeds threshold value tₕ, the timing and the value of |P(d)| are stored during period t_{d} as a candidate. If |P(d)| does not exceed the stored value within period t_{d}, the stored timing is set to the symbol timing; if P(d) exceeds the stored value within period t_{d}, this timing and the new value |P(d)| are stored again for next period t_{d}. The final stored value is the peak value of |P(d)|.

Since the detected symbol timing is disturbed by noise and delayed signals, the DFT window is set to the t_{f} period earlier than the detected timing in order to reduce the degradation as mentioned above. The value of the threshold tₕ is set to be very small in practice so that the calculated timing metric can exceed it as long as about 3 or 4 short symbols are received after signal detection. Then the circuit continuously updates the max value of timing metric until no larger value occurs during td. If signal detection takes 3 short symbols, there is no need to change T_{w}. Because the peak is always detected when all 10 symbols are received as long as T_{w}+T_{d}=10L.

Once the symbol timing has been determined, the window control function 41 is informed in order that the second preamble and data symbols of the OFDM packet may be correctly received. Window control is important for the extraction of the received samples for IFFT (Inverse Fast Fourier Transform) and discarding the guard interval (GI) based on the received correct symbol timing.

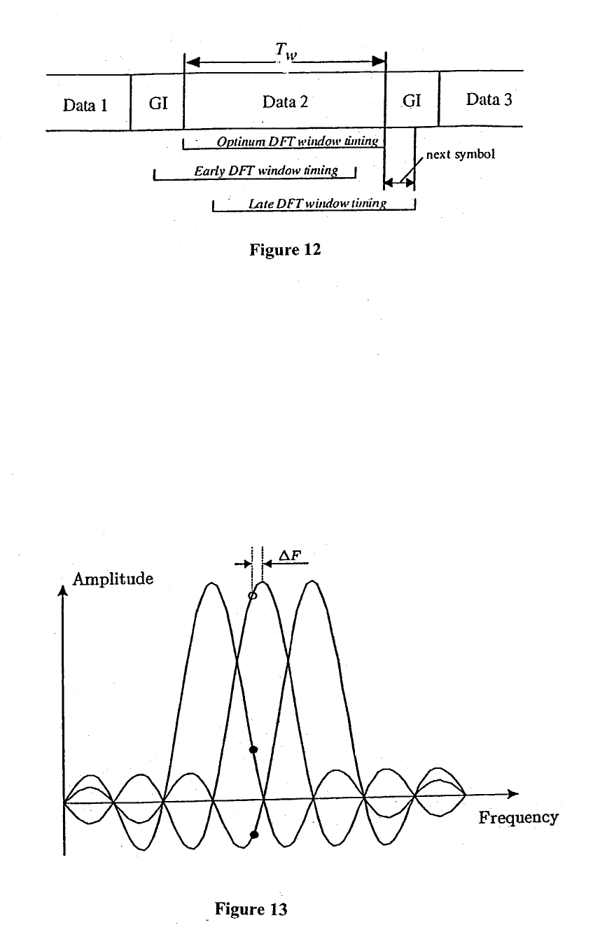

FIG. 12 illustrates window control timing for a received data symbol. Since an OFDM symbol has a guard interval prefix that is a cyclic extension of the original symbol in a multipath channel having delay signals, no degradation occurs if the DFT (discrete fourier transform) window is set sufficiently early. That is provided all the delayed signals start in the guard interval cyclic prefix, there will be no inter-symbol interference in the DFT window. In exponentially decaying Rayleigh fading channels, the error rate is degraded much more with late timing than with early timing. Because of this property, precise timing synchronization is not required for OFDM signals if the DFT window is set slightly early to eliminate the inter-symbol interference caused by symbol timing error.

The bigger W, the better. Because as W increases, more samples will be processed and higher SNR of the metric can be obtained. However because at least first three short symbols are used for signal detection and 1^{st} stage AGC, we can use W=7L to reduce the hardware complexity. However, we can also use the first three symbols and choose W=9L. Alternatively we can use T_{w}=6L and T_{d}=4L which reduces hardware cost but provides an adequate peak for detection, although SNR is reduced.

In prior art, the number of samples that is used for symbol timing is only about 2 or 3L. As W increases, more samples will be processed and higher SNR of the metric can be obtained. Therefore W=9L is better than W=4L and W=4L is better than W=L. Higher peak or plateau is better because it means higher precision in searching for the peak value. When the first 3 symbols are used for signal detection and 1^{st} AGC, the following 7 symbols will be processed for symbol timing. When D=L, W=7L−D, a peak can be achieved. If 10 symbols are used, W=10L−D=9L. The critical factor is that the sum of W and D is equal to the number of processed samples in the timing metric. When the sum is larger than the number of processed samples, a peak can also be achieved but some buffer for W is wasted. However, when the sum of W and D is smaller than the number of processed samples, the timing metric is like FIG. 9b and a plateau will occur.

4. Frequency Offset Estimation

OFDM systems are very sensitive to carrier frequency offsets since they can only tolerate offsets which are a fraction of the spacing between the subcarriers without a large degradation in system performance. The WLAN standards IEEE802.11a and HIPERLAN/2 both specify a maximum offset per user of 20 ppm. Current OFDM-based WLAN is assigned the frequency range around 5.2 GHz. So the frequency offset of 20 ppm stands for 5.2e9*20e−6=104 kHz. This means that the worst case offset as seen by a receiver can be up to 40 ppm, as it experiences the sum of the frequency offsets from both transmitter and receiver. Frequency offsets are caused not only by differences in oscillators in the transmitter and receiver but also by Doppler shifts, or phase noise introduced by non-linear channels. There are two destructive effects caused by a carrier frequency offset in OFDM systems. One is the reduction of signal amplitude in the output of the filters matched to each of the carriers (the sinc functions are shifted and no longer sampled at the peak). The other is the introduction of ICI from the other carriers which are now no longer orthogonal to the filter (see FIG. 13).

The 1^{st} preamble of an IEEE802 received burst consists of 10 repeated training symbols which are identical to each other at the receiver except for a phase shift caused by the carrier frequency offset. Because the preamble is so short the multipath channel can be considered time invariant. The multipath channel has the same effect on the identical symbols. Normally the effect of multipath channel is worked out by channel estimation but this is not necessary for the frequency offset estimation method. The frequency offset can be estimated using the phase shift. If the conjugate of a sample from the first symbol is multiplied by the corresponding sample from the second (delay time T_{d} later), the effect of the channel should cancel, and the result will have a phase of approximately

φ=πT_{d}Δf

where Δf is the frequency offset. The phase shift can be estimated by calculating the argument of P(d).

\hat{φ}−arg(P(d))

at the start of symbol timing point. Because of the 2π ambiguity of the phase, the frequency error must be smaller than Δf/2. Therefore, the frequency acquisition must ensure a rough frequency error estimate with an accuracy of better than Δf/2. In other words, if |\hat{φ}| is guaranteed to be less than π, then the frequency offset estimate is

$$Δ \hat{f} = \frac{\hat{φ}}{π {T}_{d}} .$$

However, an unambiguous frequency offset estimate is not possible, if the frequency offset to be estimated is not restricted in this range. Therefore the only way to guarantee an unambiguous frequency offset estimate is to enlarge the estimation range which can accommodate possible frequency offset. The frequency offset estimation range depends on the spaced time T_{d} between two repeated sequences. To obtain a larger estimation range for frequency offset, T_{d}, the delay time between the repeated symbol should be smaller. T_{d} can be set to mujltiples of Tₛₕₒᵣₜ.

However, a smaller T_{d} will result in some loss in the estimation precision. In order to achieve a more accurate estimation of frequency offset, T_{d} should be larger. In addition, in order to increase the SNR of the metric and hence enhance the estimation precision, the integration window length T_{w} is made as large as possible. Therefore, by adjusting T_{d} we may get a desired estimation range of frequency offset and by adjusting T_{w} we enhance the estimation precision of the frequency offset.

In the embodiment, a two-stage frequency offset estimation method is proposed to achieve both a large frequency offset estimation range and high precision. In each stage, differently spaced sample sequences (ie with T_{d} different for coarse and fine) are used to calculate the timing metric and P(d).

T_{d}=DₘT

where

Dₘ=MLₛₕₒᵣₜ

is the number of samples at the m-th stage and Lₛₕₒᵣₜ is the number of samples in one short symbol with a period of Tₛₕₒᵣₜ=LₛₕₒᵣₜT. At the first stage, D₁=Lₛₕₒᵣₜ, and thus, the largest estimation range of frequency offset is achieved at the first stage. The estimation range is the range of estimated frequency offset. From the equation

$$Δ \hat{f} = \frac{\hat{φ}}{π {T}_{d}} ,$$

we can see that when T_{d} is set to be Tₛₕₒᵣₜ, minimum value, the estimated frequency offset can reach the maximum. In prior art methods, two short symbols of the first preamble are used to do coarse frequency estimation. In the embodiment, because AGC can be done early so that more short symbols can be used, the estimation accuracy is increased. Furthermore, fine frequency estimation is processed parallely, so there is no requirement for this during the second preamble as with the prior art.

The estimated phase shift which is smaller than π is the reflection of total frequency offset, i.e.

φ₁≅\hat{φ}₁=2πΔfD₁T=2πΔ\hat{f}LₛₕₒᵣₜT

For the m-th stage, the phase shift caused by frequency offset is

$$\begin{matrix}{φ}_{m} ≅ {\hat{φ}}_{m} + 2 π \cdot z \\ = 2 πΔ \hat{f} m {L}_{short} T \\ ≅ m {\hat{φ}}_{1}\end{matrix}$$

where, \hat{φ}ₘ is the estimated phase shift at m-th stage and z is a integer and can be calculated with

$$z ≅ RND [ \frac{m {\hat{φ}}_{1} - {\hat{φ}}_{m}}{2 π} ]$$

where RND[X] represents round X to an integer. Finally, the frequency offset can be estimated with

$$\begin{matrix}Δ \hat{f} = \frac{{φ}_{m}}{2 π m {L}_{short} T} \\ = \frac{{\hat{φ}}_{m} + 2 π \cdot z}{2 π m {L}_{short} T}\end{matrix}$$

This estimated frequency offset has the same precision as that at the m-th stage and the same estimation range as that at the first stage.

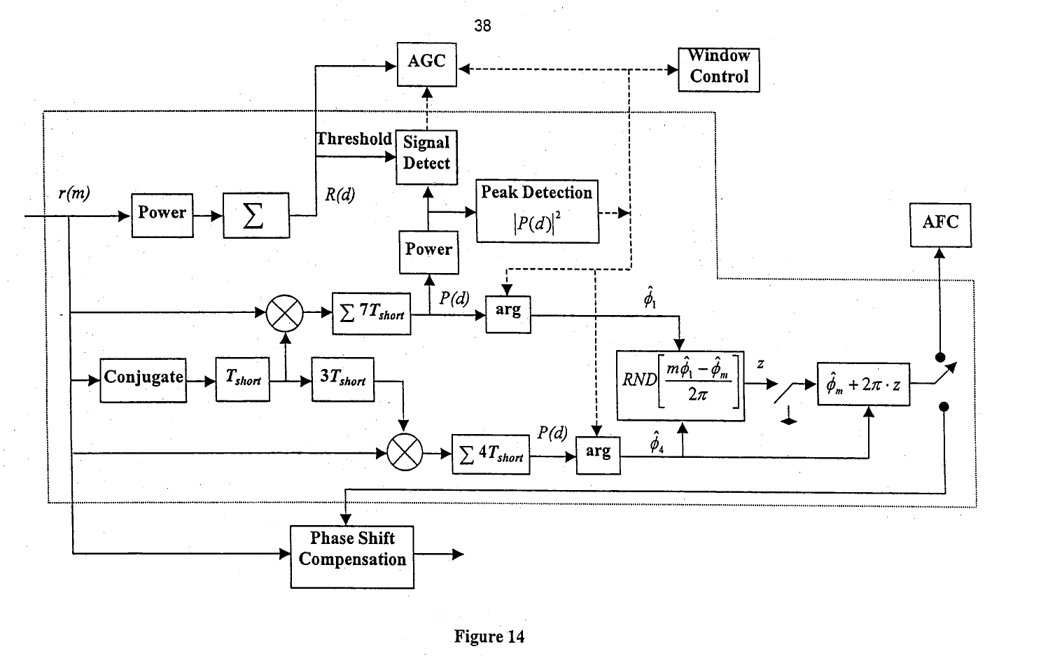

In this embodiment as shown in FIG. 14, a 2-stage estimation method is applied. Two branches of received signal flow are used to estimate frequency offset. For the two stage embodiment shown, the settings are preferably T_{d}=Tₛₕₒᵣₜ (coarse) and 4T_{SHORT}, (fine) and T_{W}=7Tₛₕₒᵣₜ (coarse) and 4Tₛₕₒᵣₜ (fine) respectively. While it is possible to use other settings, T_{d}=Tₛₕₒᵣₜ and T_{W}=7Tₛₕₒᵣₜ are preferred for coarse frequency offset estimation. This is because the maximum frequency offset estimation range can be achieved. T_{d}=4T_{SHORT}, and T_{W}=4Tₛₕₒᵣₜ are preferred for fine frequency offset. This is because the estimation accuracy can be satisfied while the hardware complexity maintained lower. Furthermore, there is then no need to do fine frequency offset in the second long preamble as required in prior art systems. The coarse branch of T_{d}=Tₛₕₒᵣₜ and Tw=7Tₛₕₒᵣₜ is used with the first preamble using 7 short symbols to obtain a coarse frequently offset estimate. The fine branch of Td=4Tshort and Tw=4Tshort is used to obtain the fine frequency offset estimation. By applying the two estimates to the above equations, the final estimated frequency offset is obtained. This is then used for the initial automatic frequency control 31 and phase compensation 40 function as described below. An implementation diagram is shown in FIG. 14.

The two-stage circuit can be used to calculate the symbol timing and frequency offset as the first stage estimation shares the same circuit as symbol timing as shown in FIG. 14.

5. AFC (Automatic Frequency Control)

According to wireless LAN protocols, linked sources are mandatory at the transmitter and at the receiver. In other words, carrier and clock frequencies are generated from the same crystal. If the carrier frequency offset is compensated through controlling this reference oscillator, the clock is simultaneously adjusted.

In the standard of IEEE802.11a and HIPERLAN/2, it is required that the transmitted center frequency tolerance and the symbol clock frequency tolerance shall be ±20 ppm maximum. The transmitter center frequency and the symbol clock frequency shall be derived from the same reference oscillator. That is, a single frequency source shall be used for both RF generation and clocking the timebase.

A frequency acquisition and tracking procedure comprising all digital baseband algorithms is proposed which uses a method of loop timing. In the loop timing method, each mobile transceiver first synchronizes itself to the base-station and then derives its uplink transmitter timing reference from the recovered downlink clock. Each mobile transceiver has a local timing reference, usually derived from a Voltage Controlled Crystal Oscillator (VCXO) 25 which provides the timing reference for the receiver A/D 22, 23 transmitter D/A and all radio frequency (RF) circuitry. Frequency offsets between the receiver and transmitter symbol clock occur due to non-idealities in the remote transceivers VCXOs 25, possibly of the order of several parts-per-million (ppm). Frequency offsets can also occur as a result of a non-linear channel or Doppler shifts.

After symbol timing is obtained (see 3 above), the frequency offset is estimated (see 4 above). Based on the estimated frequency offset for the short training preamble (i.e. the first branch), the Automatic Frequency Control (AFC) 31 controls VCXO 25 to adjust the RF and IF oscillator frequency or clock timing (14 and 24).

6. Phase Shift Compensation

Although the present two-stage frequency offset estimation method can achieve highly accurate estimated frequency offset, AFC 31 may not adjust VCXO 25 so precisely that the frequency offset can be totally removed. To obtain a fine frequency adjustment, a phase shift compensation method is applied. The coarse and fine frequency offset estimation results are combined by using equation

$$\begin{matrix}Δ \hat{f} = \frac{{φ}_{m}}{2 π {nL}_{short} T} \\ = \frac{{\hat{φ}}_{m} + 2 π \cdot z}{2 π {mL}_{short} T}\end{matrix}$$

For example, the estimated frequency offset is f₁ which is obtained using the above equation. AFC 31 can adjust the frequency to a degree of accuracy by f₂. The remaining frequency offset (f₁−f₂) is compensated by the function of phase shift compensation.

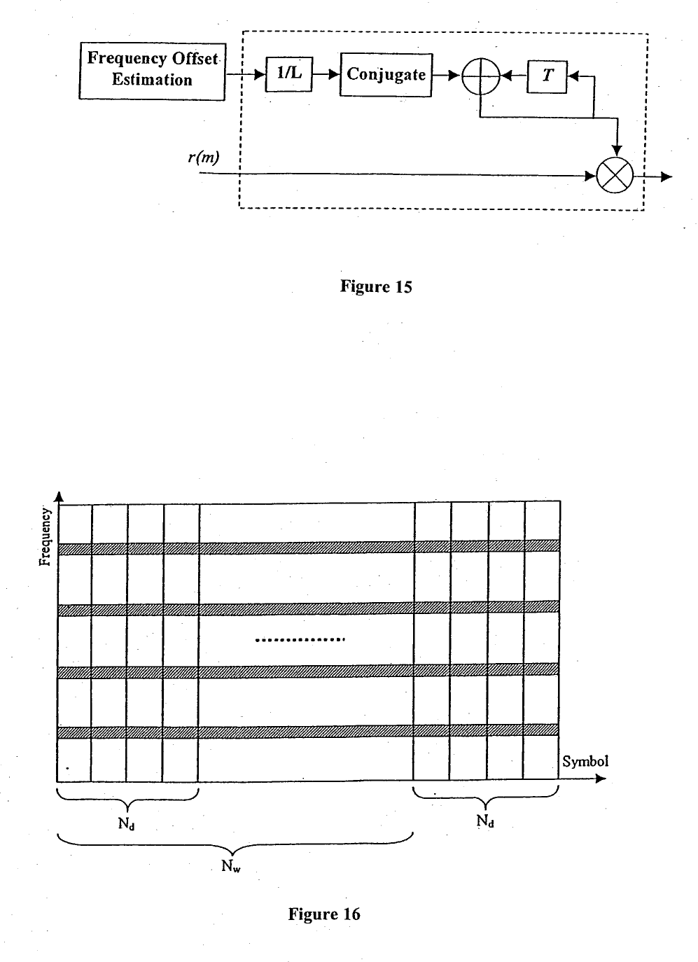

The block diagram of phase shift compensation circuit 40 is shown in FIG. 15. The phase shift estimated by the frequency offset estimation functions is input and divided by the number of samples (L) for one symbol. The conjugate of this product is the compensation phase which is integrated sample by sample. T is sample interval. i.e. the inverse of sampling rate. If sampling rate is double rate of FFT chip rate (20 MHz), i.e. 40 MHz, T is 25 ns.

7. Frequency Tracking

Although carrier acquisition is achieved with good performance, there is always a small frequency offset left. Such an error will cause phase rotation in the subsequent incoming signals. Transformed into the frequency domain, the remaining frequency offset causes a common phase shift on all subcarriers. This phase shift can be accumulated as time goes by. In addition, the channel in which the receiver is working is dynamic. Fading and Doppler spread are varying. Therefore, the resulting phase rotation is not static and is unpredictable.

To provide better robustness to fast-fading channels and a phase reference to the phase rotation over all the subcarriers caused by small frequency and symbol timing offsets, frequency tracking has to be applied. In the OFDM symbol of 802.11a, there are 4 pilot carriers inserted into 48 data carriers. The pilot signals are first extracted from the received signal and multiplied with a known pilot. By calculating the phase shift on the pilot carriers, the carrier frequency can be compensated and the phase shift for incoming samples can be tracked. The basic idea of phase shift estimation on subcarriers is the same as the frequency offset estimation. In the method of frequency offset estimation, the phase shift is obtained by calculating the correlation of a pair of samples which are identical to each other except for a phase shift. In frequency tracking, the phase shift is obtained by multiplying a pilot symbol with a conjugate pilot symbol received several symbols time later. The frequency tracking metric is written as

$$F = {\sum }_{n = 0}^{{N}_{W} - 1} {\sum }_{p = 0}^{{N}_{p} - 1} ( {R}^{*} ( p , n ) \cdot R ( p , n + {N}_{d} ) )$$

where R (p, n) is the signal on p-th pilot carrier of n-th OFDM symbol, N_{d} the number of delay symbols, N_{w} the number of integration symbols. FIG. 16 illustrates these parameters. The 4 shaded bars represent 4 pilot carriers and the other bars data carriers. The pilot carriers are used in frequency tracking. Nₚ=4 is the IEEE and Hiperlan WLAN standards. N_{d} represents the duration of (N_{d}) symbols between the two symbols processed. The product used in the above frequency tracking equation is obtained by multiplying a conjugate of a symbol with a symbol that is received N_{d} symbols later. The obtained products are integrated. N_{w} is the number of integration symbols.

After obtaining the sum of the products F, the tracked phase shift can be calculated by

\hat{φ}hd track=arg(F)

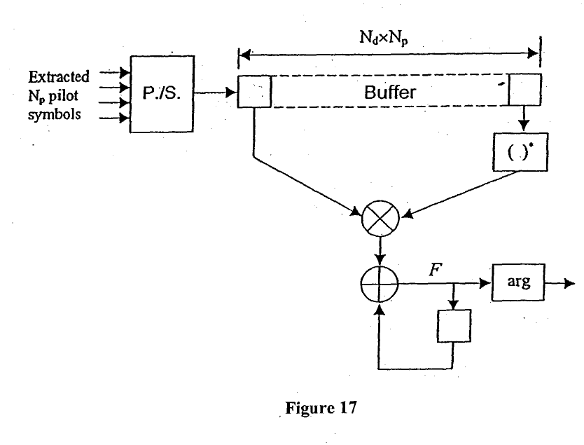

In this embodiment the phase shift estimation is processed every N_{w}+N_{d} symbols. That means the compensation output by frequency tracking will be updated every N_{w}+N_{d} symbols. An implementation diagram of this method is shown in FIG. 17.

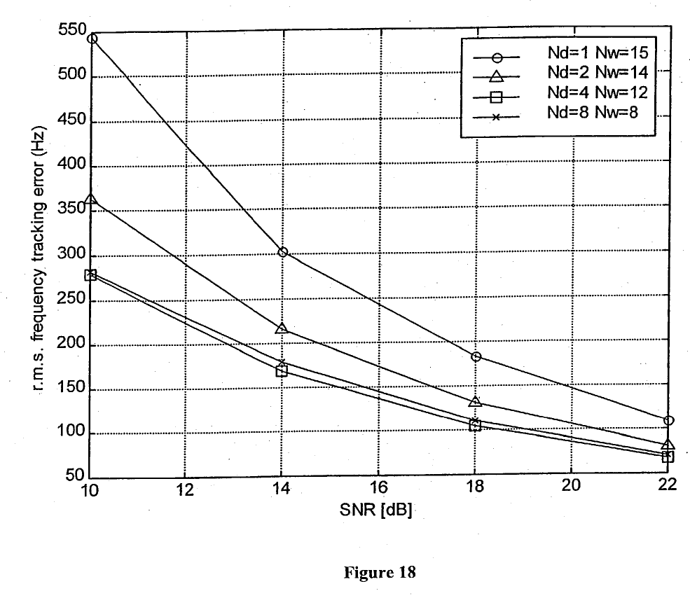

In FIG. 18, the performance of the proposed frequency tracking method in the AWGN channel is shown. As can be seen, even at SNR=10 dB, the method can achieve a precision of within 0.1 ppm. In this embodiment, N_{w} is chosen to be 12 and N_{d} is 4. In order to achieve higher accuracy frequency, N_{d} should be larger. However, in order to reduce hardware complexity, it is better to choose a smaller N_{d}. N_{d}=4 has been found to be a good compromise. The larger N_{w}, the higher the SNR. To increase the frequency of updating the phase shift compensation, the sum of N_{d} and N_{w} can be reduced. So when choosing N_{w} and N_{d}, there are some tradeoffs in the implementation.

9. Channel Estimation and Equalization

For a WLAN transceiver working in an indoor environment in which a multipath Rayleigh channel is assumed without LOS (line of sight), transmitted signals will be distorted by the multipath channel. Therefore to restore the signals, the channel state information needs to be estimated.

As is known, the transmitter transmits signals s(t) through a channel h(t). The received signal can be written as

r(t)=s(t)*h(t)+n(t)

Where n(t) is AWGN, and * denotes convolutional multiplication.

This equation can be rewritten in the frequency domain as:

\overline{R}=\overline{S}·\overline{H}+\overline{N}

where S, H and N are FFT (fast fourier transform) transformations of s, h and n.

After carrier recovery (including signal detection, AGC, frequency offset estimations) and timing detection, the receiver will know the start of an OFDM symbol. The received signals will be transformed into the frequency domain using FFT and can be written as

\overline{R}=FFT[\overline{r}]

whereby FFT function 43 outputs frequency domain signals on N_{c} sub-carriers

\overline{R}=[R(0) R(1) . . . R(N_{c})]

and FFT inputs time domain signals of N_{IFFT} samples

\overline{r}=[r(0) r(1) . . . r(N_{IFFT})]

where IFFT is reverse fast fourier transform.

The long training symbols of the preamble can be used to obtain reference amplitudes and phases for doing coherent demodulation. In the long training symbol, the signals on each subcarrier are QPSK modulated and known to the receiver. By dividing the received long training symbols by the known symbols, reference amplitudes and phases are obtained for doing coherent demodulation.

$${\overline{H}}_{e} = \frac{\overline{R}}{{R}_{store}}$$

Where Hₑ is the estimated channel for subcarriers and Rₛₜₒᵣₑ is the stored training symbol. By averaging the two identical parts of the long training symbol, coherent references can be obtained with a noise level that is 3 dB lower than the level of the data symbols. Then the estimated channel information is used for equalization where a one-tap equalizer is applied. After channel estimation and equalization, the signal for each subcarrier is demapped into binary data according to the modulation type of the subcarrier for example 16 QAM or 64 QAM. Then the data sequence is decoded according to the coding rate used. To combat the deep fading which affects the overall signal bandwidth (flat fading), the best way is to use an efficient channel code, in conjunction with a robust modulation. In the WLAN standards, convolutional coding is used with coding rates of ½, 3/4, and ⅔.

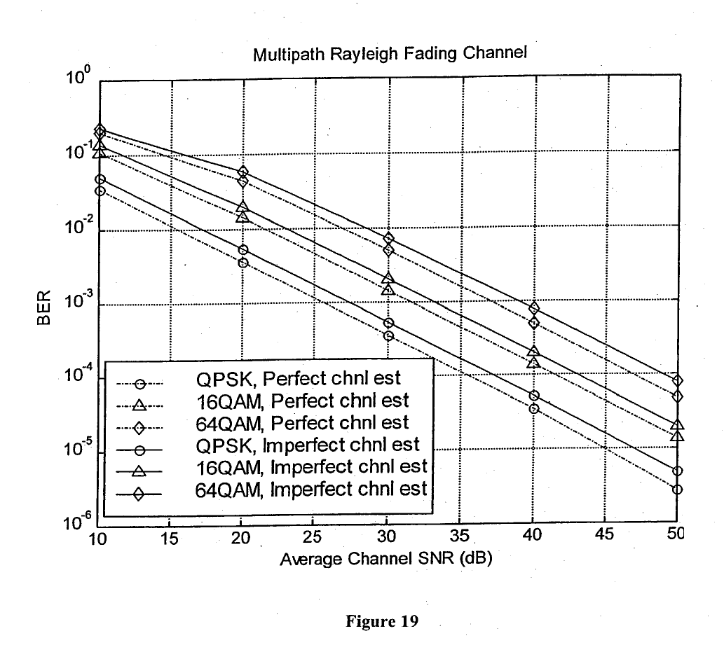

In FIG. 19, the BER performance for 64 QAM, 16 QAM and QPSK in a multipath Rayleigh channel is shown. The multipath channel is constructed according to an exponentially decaying power profile model. From the figure, we can see that the performance of the proposed method approaches that of perfect channel estimation.

The invention has been described with reference to preferred embodiments thereof. Attentions and modifications which are obvious to those skilled in the art are intended to be incorporated within the scope hereof. The various aspects of the invention are freely combinable.

1. A signal detection apparatus for an OFDM receiver, having:
means for determining the correlation of corresponding samples of two received preamble symbol samples, one said sample delayed a predetermined duration with respect to the other; signal detection being indicated when the correlation is greater than or equal to a threshold;
wherein the threshold is dependent on the signal power of the received preamble symbols.

2. An apparatus according to claim 1 further comprising means for determining the signal power of the symbol samples, and means for determining said threshold from said signal power.

3. An apparatus according to claim 2 wherein said signal power determining means further comprises means for accumulating the difference between said sample signal powers.

4. An apparatus according to claim 3 wherein said predetermined duration is of one preamble symbol.

5. An apparatus according to claim 1 wherein said correlation determining means comprises:
means for determining the product of a said sample and the conjugate of a said delayed sample:
means for accumulating said product over an integration window; and
means for accumulating the difference between said product at the beginning and end of said window.

6. An apparatus according to claim 1 wherein said samples are a first and a last sample in a correlation window having a length of one preamble symbol.

7. A method of signal detection for an OFDM receiver, the method comprising:
determining the correlation of corresponding samples of two received preamble symbols, one said sample delayed a predetermined duration with respect to the other; signal detection being indicated when the correlation is greater than or equal to a threshold;
wherein the threshold is dependent on the signal power of the received preamble symbols.
